(19) United States
(12) Patent Application Publication
(10) Pub. No.: US 2025/0166154 A1
(43) Pub. Date: May 22, 2025

(54) DEFECT DETECTION USING A MACHINE LEARNING ALGORITHM

(71) Applicant: Applied Materials Israel Ltd., Rehovot (IL)

(72) Inventors: Sergey KHRISTO, Ashdod (IL); Shih-Wei YANG, Hsinchu City (TW); Denis SIMAKOV, Rehovot (IL); Elad COHEN, Rehovot (IL); Victor EGOROV, Ramat Gan (IL)

(21) Appl. No.: 18/518,025

(22) Filed: Nov. 22, 2023

(51) Int. Cl. G06T 7/00

(52) U.S. Cl. CPC G06T 7/0004; G06T 2207/20076; G06T 2207/20081; G06T 2207/20084; G06T 2207/30148

(57) ABSTRACT

There are provided systems and methods comprising obtaining a first inspection image informative of a first area of a specimen acquired by an examination tool, feeding at least the first inspection image to a machine learning algorithm configured to determine, for each given pixel of a plurality of pixels of the first inspection image, or for each given group of pixels of a plurality of groups of pixels of the first inspection image, one or more given parameters of a given model informative of pixel intensity distribution, for said each given pixel or given group of pixels, using at least some of the one or more given parameters, or the given model associated with the one or more given parameters, and measured pixel intensity of the given pixel or group of pixels, to determine whether a defect is present in the given pixel or in the given group of pixels.

### TECHNICAL FIELD

The presently disclosed subject matter relates, in general, to the field of examination of a specimen, and more specifically, to automating the examination of a specimen.

### BACKGROUND

Current demands for high density and performance associated with ultra large-scale integration of fabricated devices require submicron features, increased transistor and circuit speeds, and improved reliability. Such demands require formation of device features with high precision and uniformity, which, in turn, necessitates careful monitoring of the fabrication process, including automated examination of the devices while they are still in the form of semiconductor wafers.

Examination processes are used at various steps during semiconductor fabrication to detect and classify defects on specimens (e.g., Automatic Defect Classification (ADC), Automatic Defect Review (ADR), etc.).

### GENERAL DESCRIPTION

In accordance with certain aspects of the presently disclosed subject matter, there is provided a system comprising one or more processing circuitries configured to obtain a first inspection image informative of a first area of a semiconductor specimen acquired by an examination tool, feed at least the first inspection image to a machine learning algorithm configured to determine, for each given pixel of a plurality of pixels of the first inspection image, or for each given group of pixels of a plurality of groups of pixels of the first inspection image, one or more given parameters of a given model informative of pixel intensity distribution, for said each given pixel, or said each given group of pixels, use at least one of the one or more given parameters, or at least part of the given model associated with the one or more given parameters, and measured pixel intensity of the given pixel or of the given group of pixels, to determine whether a defect is present in the given pixel or in the given group of pixels.

According to some embodiments, the system is configured to, for said each given pixel or for said each given group of pixels, use at least some of the one or more given parameters, or at least part of the given model associated with the one or more given parameters, to determine a probability that a defect is present in the given pixel or in the given group of pixels.

According to some embodiments, for said each given pixel or for said each given group of pixels, at least part of the given model associated with the one or more given parameters is informative of a pixel intensity probability distribution usable to determine a probability that the measured pixel intensity of the given pixel or of the given group of pixels corresponds to a defect.

According to some embodiments, for said each given pixel or for said each given group of pixels, at least one of the one or more given parameters, or at least part of the given model associated with the one or more given parameters, is usable to determine an expected pixel intensity in an absence of defects in the given pixel or in the given group of pixels.

According to some embodiments, for said each given pixel or for said each given group of pixels, at least one of the one or more given parameters, or at least part of the given model associated with the one or more given parameters, is usable to determine an expected pixel intensity in an absence of defects in the given pixel or in the given group of pixels, and a probability that a deviation from the expected pixel intensity corresponds to a defect.

According to some embodiments, for said each given pixel or for said each given group of pixels, at least one of the one or more given parameters, or at least part of the given model associated with the one or more given parameters, is informative of pixel intensity in an absence of defects in the given pixel or in the each given group of pixels, and noise in the given pixel or in the each given group of pixels.

According to some embodiments, the system is configured to use the given model to detect, on average, in different regions with a different level of noise, a maximal number of defects below a same threshold for said different regions.

According to some embodiments, the system is configured to, for said each given pixel or for said each given group of pixels, use at least some of the one or more given parameters, or at least part of the given model associated with the one or more given parameters, to differentiate between presence of a defect and presence of noise in the given pixel or in the given group of pixels.

According to some embodiments, the one or more given parameters are determined by the machine learning algorithm specifically for said each given pixel or said each given group of pixels, and comprise data informative of an expected pixel intensity in the given pixel, or in the given group of pixels, in an absence of defects in the given pixel, or in the given group of pixels, and at least one of data informative of noise present in the given pixel or in the given group of pixels, data enabling normalization of noise present in the given pixel or in the given group of pixels, or data enabling differentiating between defects and noise in the given pixel or in the given group of pixels.

According to some embodiments, the system is configured to feed, to the machine learning algorithm, in addition to the first inspection image, one or more reference images informative of one or more other areas of the semiconductor specimen, or of another semiconductor specimen.

According to some embodiments, for said each given pixel or for said each given group of pixels, the system is configured to use an output of the machine learning algorithm to determine, at least one of data informative of noise present in the given pixel or in the given group of pixels, data enabling normalization of noise present in the given pixel or in the given group of pixels, or data enabling differentiating between defects and noise in the given pixel or in the given group of pixels.

According to some embodiments, the machine learning algorithm has been trained with at least one training image and a loss function comprising, for each given pixel of a plurality of pixels of the training image, or for each group of pixels of a plurality of group of pixels of the training image, one or more parameters of a model modelling pixel intensity associated with the given pixel or with the given group of pixels.

According to some embodiments, the machine learning algorithm is configured to determine, for each given pixel of a plurality of pixels of the first inspection image, or for each given group of pixels of a plurality of groups of pixels of the first inspection image, at the same time data informative of expected pixel intensity in the given pixel or in the given group of pixels, in an absence of defects in the given pixel or in the given group of pixels, and data informative of noise present in the given pixel or in the given group of pixels.

According to some embodiments, the machine learning algorithm is configured to determine, for each given pixel of a plurality of pixels of the first inspection image, or for each given group of pixels of a plurality of groups of pixels of the first inspection image data informative of expected pixel intensity in the given pixel or in the given group of pixels, in an absence of defects in the given pixel or in the given group of pixels, and data informative of noise present in the given pixel or in the given group of pixels.

According to some embodiments, the machine learning algorithm is configured to generate, for said each given pixel or for said each given group of pixels, data informative of an expected pixel intensity in the given pixel, or in the given group of pixels, in an absence of defects in the given pixel, or in the given group of pixels, and data informative of a confidence associated with the data informative of expected pixel intensity in the given pixel or in the given group of pixels, wherein the system is configured to use measured pixel intensity of the given pixel or of the given group of pixels and data informative of the confidence to determine whether a defect is present in the given pixel or in the given group of pixels.

According to some embodiments, the system is configured to obtain a single inspection image informative of an area of a semiconductor specimen acquired by an examination tool, determine one or more defects in the area based on the single inspection image, said determination comprising feeding the single inspection image to the machine learning algorithm configured to determine, for each given pixel of a plurality of pixels of the single inspection image, or for each given group of pixels of a plurality of groups of pixels of the single inspection image, one or more given parameters of a given model informative of pixel intensity distribution, and for said each given pixel, or said each given group of pixels, using at least one of the one or more given parameters, or at least part of the given model associated with the one or more parameters, and measured pixel intensity of the given pixel or of the given group of pixels, to determine whether a defect is present in the given pixel or in the given group of pixels.

According to some embodiments, one or more training images used to train the machine learning algorithm have at least one of a smaller height or a smaller width than the first inspection image.

According to some embodiments, the system is configured to use at least some of the one or more given parameters, or at least part of the given model associated with the one or more given parameters, to generate a new image, wherein at least one of (i) or (ii) is met: (i) the new image is noise-free or contains less noise that the first inspection image; (ii) the new image is defect-free or contains less defects than the first inspection image.

In accordance with certain aspects of the presently disclosed subject matter, there is provided a method comprising one or more processing circuitries performing one or more of the features described with respect to the system (these features are therefore not repeated).

In accordance with other aspects of the presently disclosed subject matter, there is provided a non-transitory computer readable medium comprising instructions that, when executed by one or more processing circuitries, cause the one or more processing circuitries to perform operations described with reference to the method above.

In accordance with other aspects of the presently disclosed subject matter, there is provided a system comprising one or more processing circuitries configured to obtain a first training image informative of a first area of a semiconductor specimen acquired by an examination tool, feed at least the first training image to the machine learning algorithm, to train the machine learning algorithm to determine, for each given pixel of a plurality of pixels of the first training image, or for each given group of pixels of a plurality of groups of pixels of the first training image, one or more given parameters of a given model informative of pixel intensity distribution, wherein the one or more given parameters, or the given model associated with the one or more given parameters, is usable to detect presence of a defect in the given pixel or in the given group of pixels.

According to some embodiments, for said each given pixel or for said each given group of pixels, the one or more given parameters, or the given model associated with the one or more given parameters, is usable to determine pixel intensity in an absence of defects in the given pixel or in the given group of pixels.

According to some embodiments, one or more training images used to train the machine learning algorithm correspond to one or more inspection images of a semiconductor specimen, to which one or more artificial defects have been added.

In accordance with certain aspects of the presently disclosed subject matter, there is provided a method comprising one or more processing circuitries performing one or more of the features described with respect to the system (these features are therefore not repeated).

In accordance with other aspects of the presently disclosed subject matter, there is provided a non-transitory computer readable medium comprising instructions that, when executed by one or more processing circuitries, cause the one or more processing circuitries to perform operations described with reference to the method above.

In accordance with certain aspects of the presently disclosed subject matter, there is provided a non-transitory computer readable medium comprising instructions that, when executed by one or more processing circuitries, cause the one or more processing circuitries to perform: obtaining a first inspection image informative of a first area of a semiconductor specimen acquired by an examination tool, feeding at least the first inspection image to a machine learning algorithm configured to determine, for each given pixel of a plurality of pixels of the first inspection image, or for each given group of pixels of a plurality of groups of pixels of the first inspection image, one or more given parameters of a given model informative of pixel intensity distribution, for said each given pixel, or said each given group of pixels, using at least one of the one or more given parameters, or at least part of the given model associated with the one or more given parameters, to determine a new given pixel intensity value, thereby obtaining a set of new given pixel intensity values, and using the set of new given pixel intensity values to generate a new image.

According to some embodiments, each new given pixel intensity value corresponds to a given expected pixel intensity in an absence of defects in the given pixel or in the given group of pixels, and the set of new given pixel intensity values corresponds to a set of given expected pixel intensity values, wherein at least one of (i) or (ii) is met: (i) the new image is noise-free or contains less noise that the first inspection image; (ii) the new image is defect-free or contains less defects than the first inspection image.

According to some embodiments, the features described above can be implemented equivalently by a method and/or by a system (these features are therefore not repeated).

The proposed solution provides various technical advantages. At least some of them are listed hereinafter.

According to some examples, the proposed solution enables efficient and accurate detection of defects in an inspection image of a semiconductor specimen.

According to some examples, the proposed solution is operative to differentiate between defects and noise.

According to some examples, the proposed solution is a computationally efficient method for detecting defects.

According to some examples, the proposed solution enables pin-pointed defect detection. In particular, it enables predicting whether a defect is present in each pixel of an inspection image of a semiconductor specimen.

According to some examples, the proposed solution directly estimates the pixel intensity of each pixel, if it was free of defects.

According to some examples, the proposed solution is operative to estimate the level of noise present in each pixel, and to use this estimate to differentiate between defects and noise. Robustness is therefore increased.

According to some examples, the proposed solution is automatic and does not require user interaction.

According to some examples, the proposed solution is operative to determine pixel intensity without defects and/or without noise in an image of a specimen without requiring prior knowledge on this specimen or the input of an operator.

According to some examples, the proposed solution does not require prior knowledge on the specimen to detect defects and can rely only on images of the specimen.

According to some examples, the proposed solution enables detecting defects in an image of an area of a specimen, without requiring additional reference images of other areas of this specimen (or of another specimen). This enables increasing throughput, and enables to operate in scenarios in which no reference image is available.

According to some examples, the proposed solution uses a machine learning algorithm for detecting defects in an inspection image, wherein the dimensions of the training images used for training the machine learning algorithm can be smaller than the dimensions of the inspection image.

According to some examples, the proposed solution is operative to generate a defect-free image based on an inspection image of a semiconductor specimen.

According to some examples, the proposed solution is operative to generate a denoised image based on an inspection image of a semiconductor specimen.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2 illustrates a generalized flow-chart of a method of detecting defects in each pixel of an inspection image.

FIG. 3 illustrates a non-limitative example of an inspection image informative of an area (such as a die) of a specimen.

FIG. 4 illustrates a non-limitative example of a probability model modelling pixel intensity in a pixel of an inspection image, wherein one or more parameters of the model is informative of pixel intensity distribution in the absence of defects in the pixel.

FIG. 5A illustrates a generalized flow-chart of another method of detecting defects in each pixel of an inspection image.

FIG. 5B illustrates a generalized flow-chart of another method of detecting defects in each pixel of an inspection image.

FIG. 6 illustrates a non-limitative example of a probability model modelling pixel intensity in a pixel of an inspection image, wherein parameters of the model are informative of the expected pixel intensity in the absence of defects in the pixel and of the noise in the pixel.

FIG. 7 illustrates another non-limitative example of a probability model modelling pixel intensity in a pixel of an inspection image, wherein parameters of the model are informative of the expected pixel intensity in the absence of defects in the pixel and of the noise in the pixel.

FIG. 8 illustrates a generalized flow-chart of another method of detecting defects in each pixel of an inspection image.

FIG. 9 illustrates a non-limitative example of a plurality of inspection images informative of different areas (such as different dies) of a specimen.

FIG. 10 illustrates a generalized flow-chart of a method of training a machine learning algorithm to detect defects in each pixel of an inspection image.

FIG. 11 illustrates a non-limitative example of a plurality of training images informative of different areas (such as different dies) of a specimen.

FIG. 12 illustrates a non-limitative example of the method of FIG. 10.

FIG. 13 illustrates a generalized flow-chart of a method of generating training images.

FIG. 14 illustrates a non-limitative example of the method of FIG. 13.

FIG. 15 illustrates a generalized flow-chart of a method of generating training images.

FIG. 16 illustrates a comparison between a training image used in the training of the machine learning algorithm and an inspection image fed to the machine learning algorithm during run-time examination.

FIG. 17 illustrates a generalized flow-chart of a method of generating a new image with less noise (denoised image) and/or with less defects.

FIG. 18 illustrates an example of the method of FIG. 17.

FIG. 19 illustrates a generalized flow-chart of a method of generating new images.

FIG. 20 illustrates an example of the method of FIG. 19.

### DETAILED DESCRIPTION OF EMBODIMENTS

Run-time examination can employ a two-phase procedure, e.g., inspection of a specimen followed by review of sampled locations of potential defects. In the first phase, a defect map is produced to show suspected locations on the specimen having high probability of a defect. During the second phase, at least some of the suspected locations are more thoroughly analyzed with relatively high resolution.

In at least some of the conventional prior art methods, during the first phase, images of a plurality of dies are acquired. In order to detect whether a defect is present in a current image of a given die of a specimen, the current image is compared to images of other dies of the specimen. Differences between the images of different dies are used to detect potential defects. This approach is however not always accurate. New methods and systems for detecting defects are proposed hereinafter. Additional applications of these new methods and systems are also described hereinafter.

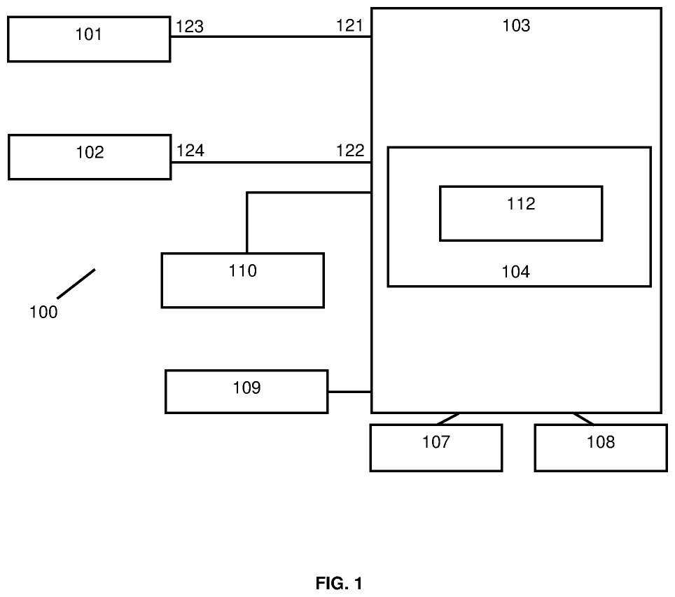

Attention is drawn to FIG. 1 illustrating a functional block diagram of an examination system 100 in accordance with certain examples of the presently disclosed subject matter. The examination system 100 illustrated in FIG. 1 can be used for examination of a specimen (e.g., of a wafer and/or parts thereof) as part of the specimen fabrication process. The illustrated examination system 100 comprises computer-based system 103 capable of automatically determining defect-related information using images obtained during specimen fabrication. System 103 can be operatively connected to one or more low-resolution examination tools 101 and/or one or more high-resolution examination tools 102 and/or other examination tools. The examination tools are configured to capture images and/or to review the captured image(s) and/or to enable or provide measurements related to the captured image(s). System 103 can be further operatively connected to CAD server 110 and data repository 109.

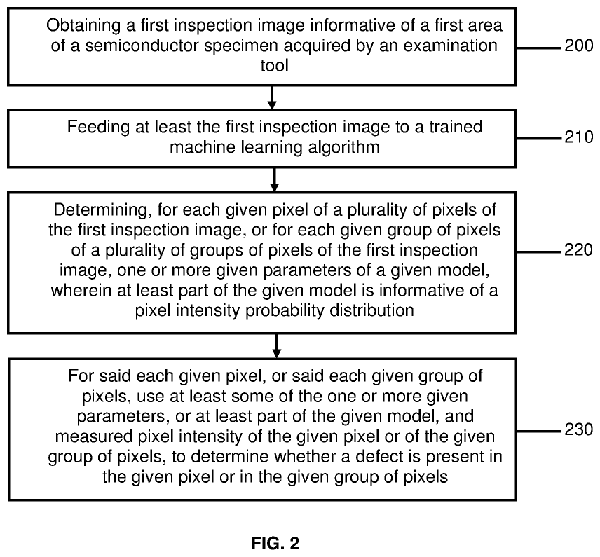

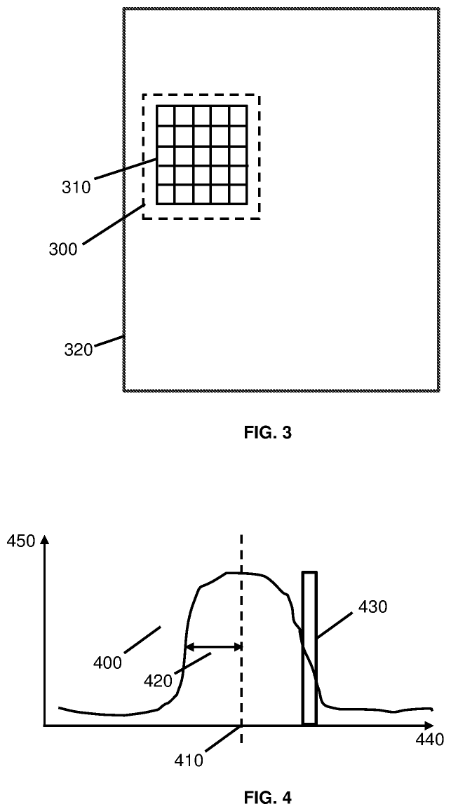

System 103 includes a processing circuitry 104, which includes one or more processors and one or more memories. The processing circuitry 104 is configured to provide all processing necessary for operating the system 103 as further detailed hereinafter (see methods described in FIGS. 2, 5, 8, 10, 13, 15, 17 and 19 which can be performed at least partially by system 103 and/or system 100).

The processing circuitry 104 is configured to execute one or more functional modules in accordance with computer-readable instructions implemented on a non-transitory computer-readable memory of the processing circuitry 104 (or operatively coupled to the processing circuitry 104). The one or more functional modules include at least one machine learning algorithm 112 (also called machine learning model), such as a deep neural network (DNN).

By way of non-limiting example, the layers of the machine learning algorithm 112 (e.g., DNN) can be organized in accordance with Convolutional Neural Network (CNN) architecture, such as a fully Convolutional Neural Network (CNN). This is not limitative.

In other examples, the layers of the machine learning algorithm 112 (e.g., DNN) can be organized in accordance with the Recurrent Neural Network architecture, Recursive Neural Networks architecture, Generative Adversarial Network (GAN) architecture, or otherwise. Optionally, at least some of the layers can be organized in a plurality of DNN sub-networks. Each layer of the DNN can include multiple basic computational elements (CE), typically referred to in the art as dimensions, neurons, or nodes.

Generally, computational elements of a given layer can be connected with CEs of a preceding layer and/or a subsequent layer. Each connection between a CE of a preceding layer and a CE of a subsequent layer is associated with a weighting value. A given CE can receive inputs from CEs of a previous layer via the respective connections, each given connection being associated with a weighting value which can be applied to the input of the given connection. The weighting values can determine the relative strength of the connections and thus the relative influence of the respective inputs on the output of the given CE. The given CE can be configured to compute an activation value (e.g., the weighted sum of the inputs) and further derive an output by applying an activation function to the computed activation. The activation function can be, for example, an identity function, a deterministic function (e.g., linear, sigmoid, threshold, or the like), a stochastic function, or other suitable function. The output from the given CE can be transmitted to CEs of a subsequent layer via the respective connections. Likewise, as above, each connection at the output of a CE can be associated with a weighting value which can be applied to the output of the CE prior to being received as an input of a CE of a subsequent layer. Further to the weighting values, there can be threshold values (including limiting functions) associated with the connections and CEs.

The weighting and/or threshold values of the machine learning algorithm 112 (e.g., DNN) can be initially selected prior to training, and can be further iteratively adjusted or modified during training to achieve an optimal set of weighting and/or threshold values in a trained DNN. After each iteration, a difference (also called loss function) can be determined between the actual output produced by the machine learning algorithm 112 (e.g., DNN) and the target output associated with the respective training set of data. The difference can be referred to as an error value. Training can be determined to be complete when a cost or loss function indicative of the error value is less than a predetermined value, or when a limited change in performance between iterations is achieved. Optionally, at least some of the DNN subnetworks (if any) can be trained separately, prior to training the entire DNN.

System 103 is configured to receive input data. Input data can include data (and/or derivatives thereof and/or metadata associated therewith) produced by the examination tools and/or data produced and/or stored in one or more data repositories 109 and/or in CAD server 110 and/or another relevant data depository. It is noted that input data can include images (e.g., captured images, images derived from the captured images, simulated images, synthetic images, etc.) and associated numeric data (e.g., metadata, hand-crafted attributes, etc.). It is further noted that image data can include data related to a layer of interest and/or to one or more other layers of the specimen.

By way of non-limiting example, a specimen can be examined by one or more low-resolution examination machines 101 (e.g., an optical inspection system, low-resolution SEM, etc.). The resulting data (low-resolution image data 121), informative of low-resolution images of the specimen, can be transmitted-directly or via one or more intermediate systems-to system 103. Alternatively, or additionally, the specimen can be examined by a high-resolution machine 102, such as a scanning electron microscope (SEM), an Atomic Force Microscopy (AFM) or an optical examination tool (such as, but not limited to, Enlight Optical Inspection System of the Applicant). The resulting data (high-resolution image data 122) informative of high-resolution images of the specimen, can be transmitted-directly, or via one or more intermediate systems-to system 103.

It is noted that image data can be received and processed together with metadata (e.g., pixel size, text description of defect type, parameters of image capturing process, etc.) associated therewith.

Upon processing the input data (e.g. low-resolution image data and/or high-resolution image data, together with other data as, for example, design data, synthetic data, etc.), system 103 can send instructions 123 and/or 124 to any of the examination tool(s), store the results (such as data informative of the location of the defects) in a storage system 107, render the results via a computer-based graphical user interface GUI 108 and/or send the results to an external system.

Those versed in the art will readily appreciate that the teachings of the presently disclosed subject matter are not bound by the system illustrated in FIG. 1; equivalent and/or modified functionality can be consolidated or divided in another manner and can be implemented in any appropriate combination of software with firmware and/or hardware.

Without limiting the scope of the disclosure in any way, it should also be noted that the examination tools can be implemented as inspection machines of various types, such as optical imaging machines, electron beam inspection machines, and so on. In some cases, the same examination tool can provide low-resolution image data and high-resolution image data. In some cases, at least one examination tool can have metrology capabilities.

It is noted that the examination system illustrated in FIG. 1 can be implemented in a distributed computing environment, in which the aforementioned functional modules shown in FIG. 1 can be distributed over several local and/or remote devices, and can be linked through a communication network. It is further noted that in other embodiments at least some examination tools 101 and/or 102, data repositories 109, storage system 107 and/or GUI 108 and/or CAD server 110 can be external to the examination system 100 and operate in data communication with system 103. System 103 can be implemented as stand-alone computer(s) to be used in conjunction with the examination tools. Alternatively, the respective functions of the system can, at least partly, be integrated with one or more examination tools.

Attention is now drawn to FIG. 2, which describes a method enabling defect defection in an image of a semiconductor specimen.

The method of FIG. 2 includes (operation 200) obtaining a first inspection image 300 informative of a first area 310 (or of a plurality of areas) of a semiconductor specimen 320. The first inspection image 300 is acquired by an examination tool (such as examination tool 101 and/or examination tool 102). Note that the first inspection image 300 may have been acquired by an optical examination tool, or by an electron beam examination tool, or by another adapted examination tool.

The first inspection image 300 includes a plurality of pixels. Each pixel is associated with a measured pixel intensity. The measured pixel intensity can be expressed e.g., as a grey level intensity, or using any other adapted convention. The measured pixel intensity can be provided by the examination tool 101 and/or 102.

The method of FIG. 2 further includes feeding (operation 210) at least the first inspection image 300 to the trained machine learning algorithm 112. Methods for training the machine learning algorithm 112 are described hereinafter.

The machine learning algorithm 112 determines (operation 220), for each given pixel of a plurality of pixels of the first inspection image 300 (such as the pixels informative of the first area 310), or for each group of pixels of a plurality of groups of pixels of the first inspection image 300, data which can be used to determine expected pixel intensity in the given pixel or in the given group of pixels, in an absence of defects in the given pixel or in the given group of pixels. A group of pixels can correspond to a few adjacent pixels in the first area 310.

The machine learning algorithm 112 determines (at operation 220), for each given pixel of a plurality of pixels of the first inspection image 300 (such as the pixels informative of the first area 310), or for each group of pixels of a plurality of groups of pixels of the first inspection image 300, one or more given parameters of a given model informative of pixel intensity distribution (also called probability distribution, statistical model, probability model or probability function). A pixel intensity distribution can correspond to a function modelling the distribution of pixel intensity. For example, the function can link the pixel intensity value(s) to the number of non-defective pixels associated with these pixel intensity value(s). Equivalently, the function can link the pixel intensity value(s) to a probability of a non-defective pixel to be associated with this pixel intensity. This is not limitative. The probability distribution is usable to determine a probability that the measured pixel intensity of the given pixel or the given group of pixels corresponds to a defect.

In particular, at least part of the given model (that is to say at least part of the probability distribution of the given model) can model a pixel intensity distribution (also called pixel probability distribution, or pixel statistical distribution) in an absence of defects in the given pixel or in the given group of pixels. The pixel intensity distribution can model the expected pixel intensity of each pixel in an absence of defects, and a probability that a deviation thereof corresponds to a defect.

Since the given model (obtained for a given pixel or group of pixels) can be informative of the expected pixel intensity in the given pixel, or in the given group of pixels, in the absence of defects in this given pixel of group of pixels, it can be used to determine expected pixel intensity in an absence of defect in the given pixel (or in the given group of pixels).

In some examples, the method enables predicting, for each pixel of the first inspection image 300, the (estimated) pixel intensity that would be present in this pixel, should this pixel be free of defects. In some examples, one or more of the parameters output by the machine learning model 112 for each pixel directly correspond to the (estimated) pixel intensity that would be present in this pixel, should this pixel be free of defects. In other examples, one or more of the parameters output by the machine learning model 112 for each pixel can be processed to estimate the pixel intensity that would be present in this pixel, should this pixel be free of defects.

The type of parameters estimated by the machine learning algorithm 112 can be the same for the plurality of pixels (for example, average value of a model, variance of a model, etc.). However, the values of the parameters estimated by the machine learning algorithm 112 can be different for each pixel. Note that the machine learning algorithm 112 is able to explicitly estimate and output the values of the parameters of the model modelling pixel intensity in each given pixel. The type and number of parameters are defined in the training phase of the machine learning algorithm 112. Similarly, the model for which these parameters are output by the machine learning algorithm 112 can be defined during the training phase. In particular, these parameters can be present in a loss function used to train the machine learning algorithm 112. As a consequence, during the prediction phase, the machine learning algorithm 112 is able to predict the values of these parameters for each pixel (or group of pixels).

In some examples, the expected pixel intensity (in the absence of defects) can correspond to the mean (or average) of the probability distribution of the model.

In some examples, the model can correspond to a Gaussian function (normally distributed random variable). The Gaussian function is only an example of a probability model that can be used, or various other probability models (which are usable e.g., for modelling a distribution of values) can be used. Another non-limitative example of a probability model that can be used is a Gamma distribution.

For each pixel, the machine learning algorithm 112 estimates the values of the parameter(s) of the model. In some examples in which the model is a Gaussian function, the parameters can include the average (also called expected value), noted “μ” (which corresponds to the expected pixel intensity in the absence of defects), and the standard deviation, noted “σ” (which is an estimate of the noise present in the pixel). As mentioned above, different values (μ and/or σ) can be obtained for each pixel.

In some examples in which the model is a Gamma distribution, the parameters can include the parameters a (called shape parameter) and β (called inverse scale parameter), or the parameters k (called shape parameter) and θ (also called scale parameter). The expected pixel intensity (in the absence of defects) can correspond to the mean value kθ or α/β.

Note that the probability model can be a symmetrical model or a non-symmetrical model.

Note that even if two pixels have the same measured grey level intensity, the method can determine different values for the estimated pixel intensity, should each pixel have been free of defects.

The method of FIG. 2 further includes (operation 230), for each given pixel or for each given group of pixels of the plurality of pixels, using at least some of the one or more given parameters, or at least part of the given model (defined by the one or more given parameters), to determine whether a defect is present in the given pixel or in the given group of pixels.

Operation 230 enables determining, for each pixel (or group of pixels), whether a defect is present in the pixel (or group of pixels). Operation 230 can generate, for each pixel of the first inspection image 300, a prospect (also called probability, or score) that a defect is present. If the prospect (probability, or score) is above or equal to a threshold, a defect is detected. If the prospect (probability, or score) is below a threshold, it is concluded that the pixel does not include a defect. The detected defects can be output (with their location) on a display. Note that this determination corresponds to the determination of a candidate defect. As explained above, each candidate defect can be further reviewed by a high-resolution examination tool (e.g., high-resolution SEM) in order to confirm whether this candidate defect is an actual defect.

In some examples, operation 230 can include (for each given pixel or group of pixels) using the given parameters and/or the given model (defined by the given parameters) to determine the expected pixel intensity in the given pixel (or group of pixels), should it be free of defects. It can further include comparing, for each given pixel (or a given group of pixels), the measured pixel intensity of the given pixel (or given group of pixels) with the expected pixel intensity generated by the machine learning algorithm 112 (in case no defect is present). If this comparison indicates that the difference between the measured pixel intensity and the expected pixel intensity is above or equal to a threshold, this can be considered as a defect. If this comparison indicates that the difference between the measured pixel intensity and the expected pixel intensity is below the threshold, this can be considered as an absence of defect. This is not limitative, and other methods can be used to determine whether a defect is present, as explained hereinafter.

The method of FIG. 2 can be performed during run-time scanning of the specimen by an examination tool. Each time a new image is provided by the examination tool (e.g., for each new die), it can be processed according to the method of FIG. 2.

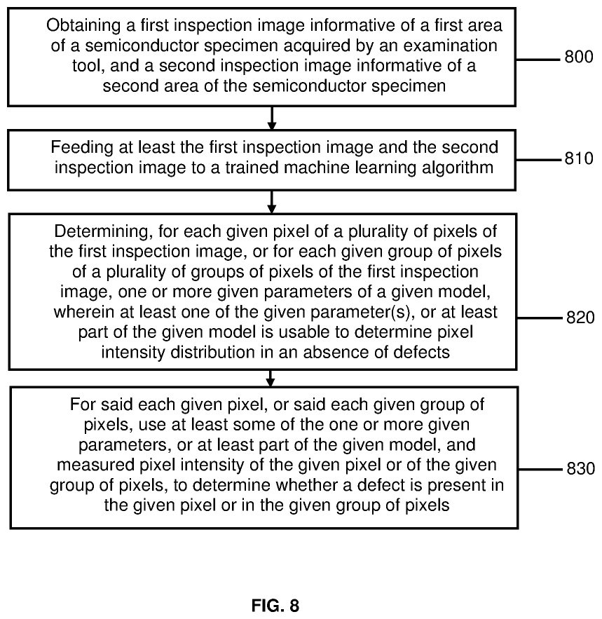

In some examples, the machine learning algorithm 112 can be fed, in addition to the first inspection image informative of the first area, with one or more additional inspection images informative of additional area(s) of the same specimen, or of another specimen. The additional area(s) can match a similarity criterion with the first area. For example, they can correspond to similar dies. This will be discussed further hereinafter with reference to FIG. 8.

The method of FIG. 2 can be also performed with a single image. In other words, it is sufficient to feed a single inspection image of an area to the machine learning algorithm 112 to detect defects in this area, without requiring feeding additional reference images of other areas to the machine learning algorithm 112. This constitutes a technical advantage, since, in at least some cases, no additional reference images are available. For example, some specimens are made of a single die (such as, but not limited to, a Graphical Processing Unit).

FIG. 4 illustrates a non-limitative example of a model 400 modelling pixel intensity distribution of a given pixel. At least part of the model models the pixel intensity distribution in an absence of defects. As mentioned above, the values of the parameters of the model can differ from one pixel to another. The abscissa 440 represents the probability and the ordinate 450 represents the pixel intensity.

In the example of FIG. 4, the model 400 is a Gaussian model. The machine learning algorithm 112 can be trained to determine the average 410 of the model (“u”) and the standard deviation 420 (noted “o”) of the model. The average 410 (“u”) corresponds to the expected pixel intensity of the given pixel, when no defect is present in the pixel. In other words, a prediction of the pixel intensity of the given pixel, should it have been defect free, is generated by the machine learning algorithm 112.

In the example of FIG. 4, the measured pixel intensity of the given pixel (for which the values of the parameters of the model 400 have been estimated by the machine learning algorithm 112) is represented as reference 430. As visible in FIG. 4, it differs from the expected pixel intensity 410 (when no defect is present). A deviation between the measured pixel intensity and the average 410 of the model can be used to determine the probability that the measured pixel intensity corresponds to a defect. It will be explained hereinafter that in some examples, the given model can be used to differentiate between a deviation that is due to a defect, and a deviation that is due to noise.

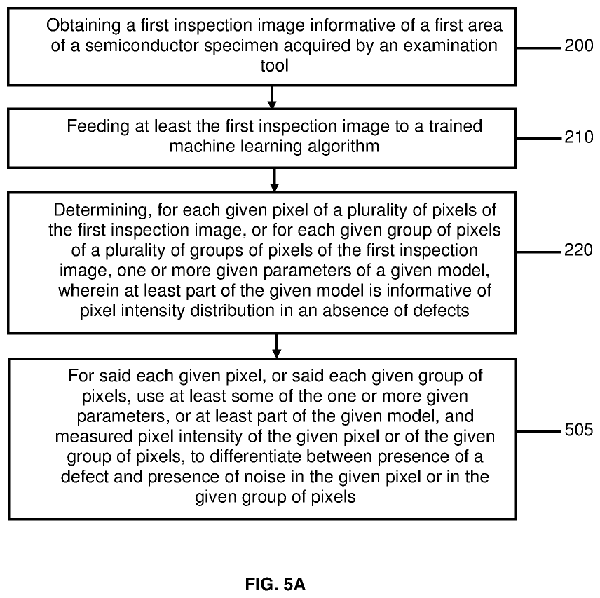

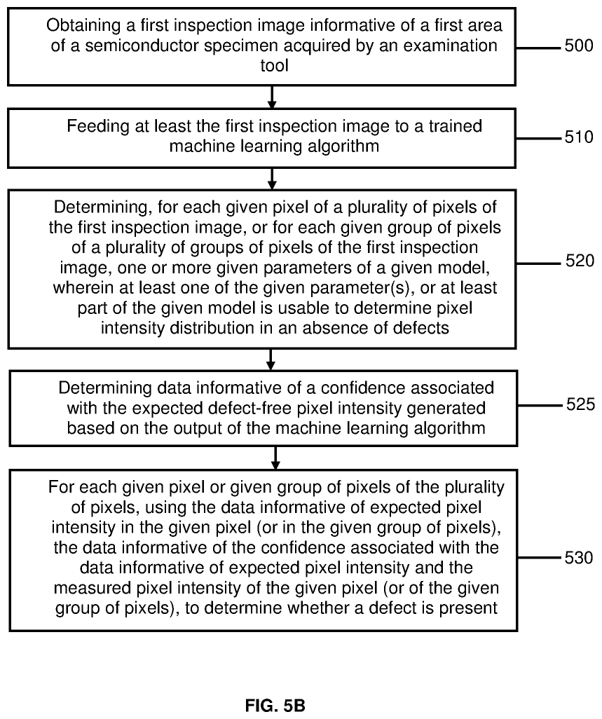

Attention is now drawn to FIG. 5A.

The method of FIG. 5A includes operations 200, 210 and 220, already described with reference to FIG. 2.

The method of FIG. 5A further includes (operation 505) using at least some of the one or more given parameters, or at least part of the given model (associated with the one or more given parameters), and measured pixel intensity of the given pixel or of the given group of pixels, to differentiate between presence of a defect and presence of noise in the given pixel or in the given group of pixels.

Indeed, it can occur that although there is a difference between the measured pixel intensity and the expected pixel intensity (in case no defect is present), this does not correspond to a defect, but rather to noise present in this pixel. Noise can be caused by various factors, such as (but not limited to), noise caused by the examination tool, noise caused by the manufacturing process (but which does not constitute a defect to be identified), etc.

The method of FIG. 5A enables detecting the same (maximal) number of defects between different areas, even if these different areas are associated with a different level of noise. In particular, it is possible to detect the same (maximal) number of defects between an area with a high level of noise and an area with a low level of noise.

On average, it is expected to get a certain number of defects for a given surface (called hereinafter expected number of defects). Note that it can occur that a specimen contains a region with an unusual number of defects, which is above the expected number. However, the method enables detecting, on average, the same (maximal) number of expected defects between various different areas (certain areas being associated with a high level of noise and certain areas being associated with a low level of noise). This enables obtaining a constant false alarm rate.

In some examples, the method of FIG. 5A includes using the given model (obtained for each given pixel or given group of pixels, and defined by the one or more given parameters output by the machine learning model) and the measured pixel intensity of the given pixel (or given group of pixels) to determine a score (probability) that the given pixel (or given group of pixels) corresponds to a defect.

In some examples, the following (non-limitative) scores can be used:

$$score = 0.5 - {\int }_{- ∞}^{c} pdf ( x ) dx , \\ in case the measured pixel intensity c is smaller \\ than the median or average of the distribution pdf ( x ) ; \qquad Equation 1$$

$$score = 0.5 - {\int }_{c}^{∞} pdf ( x ) dx , \\ in case the measured pixel intensity c is smaller \\ \\ \\ than the median or average of the distribution pdf ( x ) .$$

In this equation, pdf(x) is the probability distribution modelling the pixel intensity (for example, Gaussian distribution, Gamma distribution, or other probability distributions, etc.). The integral of the distribution is performed in an interval which depends on the measured pixel intensity of the given pixel. The probability distribution models the expected pixel intensity (in an absence of defects and noise) and the probability that a deviation from this expected pixel intensity corresponds to a defect (and not to noise). By computing the score using an integral of the probability distribution, it is possible to determine a probability that the pixel intensity corresponds to a defect, and not to noise. In other words, a differentiation between defects and noise is performed.

If the score is above or equal to a threshold, a defect is detected. If the score is below the threshold, a defect is not detected.

In some examples, it is possible to compute explicitly data which indicates, for each pixel, the level of noise. This is described with reference to FIG. 5B, which describes another non-limitative example of an implementation of the method of FIG. 5A. The method of FIG. 5B can include determining the confidence of the prediction of the expected pixel intensity (in case no defect is present) and using this confidence to determine whether a defect is present.

Data informative of the confidence of the prediction of the expected pixel intensity (in case no defect is present) is an estimate of the noise present in the pixel. If there is a small confidence (which corresponds to a large standard deviation o in case of a Gaussian model), this indicates that there is a high level of noise in the pixel. In other words, it is expected that the pixel intensity can encounter large variations around the expected pixel intensity (in case no defect is present), but these variations are not indicative of a defect. If there is a high confidence (which corresponds to a small standard deviation o in case of a Gaussian model), this indicates that there is a low level of noise in the pixel. In other words, the pixel intensity is not expected to encounter significant variations around the expected pixel intensity (in case no defect is present), and presence of significant variations is likely to be indicative of a defect. In light of the foregoing, the method of FIG. 5B can perform a normalization of the noise, in order to differentiate, in each pixel, between actual defects and noise.

The method of FIG. 5B includes obtaining (operation 500) a first inspection image informative of a first area of a semiconductor specimen acquired by an examination tool. Operation 500 is similar to operation 200.

The method of FIG. 5B further includes feeding (operation 510) at least the first inspection image 300 to the trained machine learning algorithm 112. Operation 510 is similar to operation 210.

The machine learning algorithm 112 generates (operation 520), for each given pixel of a plurality of pixels of the first inspection image 300, or for each given group of pixels of a plurality of groups of pixels of the first inspection image 300, one or more given parameters of a given model, wherein at least part of the given model is informative of pixel intensity distribution in an absence of defects. At least some of the given parameter(s) and/or the given model (defined by the given parameter(s)) can be used to determine, for each given pixel, the expected defect-free pixel intensity of the given pixel. As mentioned above, the defect-free pixel intensity can correspond to the mean (or average) of the given model. In addition, the given parameter(s) can correspond, or can be used (operation 525), to determine data informative of a confidence associated with the expected defect-free pixel intensity generated based on the output of the machine learning algorithm. This data is also informative of the noise (which does not constitute a defect to be detected) present in each given pixel or in each given group of pixels.

In some examples, the method enables generating data informative of expected pixel intensity (in case no defect is present) for each pixel, and data informative of the confidence of the prediction for each pixel (data informative of noise in each pixel), based on an output of the same (single) machine learning algorithm 112.

A map can be output, which includes, for each pixel of the first inspection image 300, the (estimated) pixel intensity that would be present in this pixel, should this pixel have been free of defects, and the data informative of a confidence associated with the data informative of expected pixel intensity (which is also informative of the noise present in the pixel).

The machine learning algorithm 112 is able to estimate the noise specifically in each pixel, or to provide parameters specific for each pixel, enabling obtaining information on the noise present in each pixel. The value of the estimate of the noise can differ from one pixel to another.

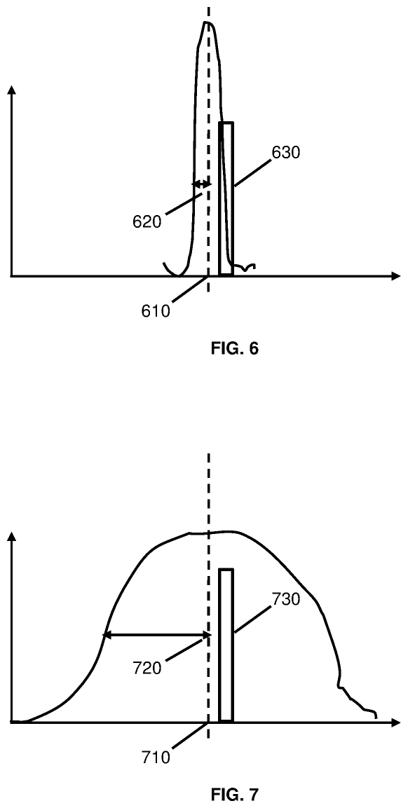

As explained above, data informative of the confidence indicates to which extent the expected pixel intensity (corresponding to a configuration without defect) is reliable. If the confidence is high, this indicates that a small deviation of the measured pixel intensity from the expected pixel intensity has a large likelihood to correspond to a defect. This is illustrated in FIG. 6, in which the standard deviation 620 (which indicates the level of confidence of the expected pixel intensity, and in turn, the level of noise) is small. Therefore, a small deviation of the measured pixel intensity 630 from the expected pixel intensity 610 (relative to the standard deviation 620), as illustrated in FIG. 6, is likely to be indicative of a defect.

If the confidence is high, this indicates that a small deviation of the measured pixel intensity from the expected pixel intensity has a small likelihood to correspond to a defect. Only a certain deviation (above a threshold) of the measured pixel intensity from the expected pixel intensity has a high likelihood to correspond to a defect. This is illustrated in FIG. 7, in which the standard deviation 720 (which indicates the level of confidence of the expected pixel intensity) is small. Therefore, only a large deviation of the measured pixel intensity 730 from the expected pixel intensity 710 (relative to the standard deviation 720) is likely to be indicative of a defect.

The method of FIG. 5B further includes (operation 530), for each given pixel (or given group of pixels) of the plurality of pixels, using the data informative of expected pixel intensity in the given pixel (or in the given group of pixels), the data informative of the confidence associated with the data informative of expected pixel intensity (data informative of the noise) and the measured pixel intensity of the given pixel (or of the given group of pixels), to determine whether a defect is present.

In particular, for each given pixel, the measured pixel intensity can be compared to the expected pixel intensity of the given pixel. This comparison can be normalized by using the data informative of the confidence (data informative of the noise). In other words, the machine learning algorithm 112 outputs built-in data enabling normalization of the noise.

According to some examples, the following non-limitative equation can be used, in order to compute a score for each given pixel (this score is particularly suitable for symmetric distributions):

$${\int }_{c}^{2 μ - c} p d f ( x ) d x \qquad Equation 2$$

In this equation, pdf (x) is the probability distribution (for example, Gaussian distribution, Gamma distribution, or other probability distributions, etc., associated with the one or more given parameters output by the machine learning algorithm 112), c is the measured pixel intensity of the given pixel and u is the mean value of the probability distribution.

If the score (as mentioned in Equation 2) is above or equal to a threshold, a defect can be detected in the given pixel (or in the given group of pixels). If the score is below the threshold, this indicates an absence of defects in the given pixel (or in the given group of pixels).

In case the probability distribution is a Gaussian distribution, the score for each pixel (as indicated by Equation 2) reads:

$$\frac{\vert c - μ \vert}{σ} \qquad Equation 3$$

In this equation, c is the measured pixel intensity of the given pixel, u is the mean value of the Gaussian distribution, which corresponds to the expected pixel intensity (as output by the machine learning algorithm 112 for each pixel, in case no defect is present), and σ is the standard deviation of the Gaussian model, which corresponds to data informative of the confidence (as output by the machine learning algorithm 112 for each pixel—as mentioned above, o is informative of the noise). If the score (as mentioned above) is above or equal to a threshold, a defect can be detected in the given pixel (or in the given group of pixels). If the score is below the threshold, this indicates an absence of defects in the given pixel (or in the given group of pixels).

Usage of data informative of the noise (noted e.g., a) in each given pixel enables normalizing the noise, and therefore enables differentiating between noise and defects in each given pixel.

If σ is high, this indicates that the level of noise present in the given pixel is high. As a consequence, even if the measured pixel intensity differs from the expected pixel intensity, this does not necessarily mean that a defect is present, but this could rather be due to noise. This can be assessed separately for each given pixel by using data informative of the noise (e.g., σ in a Gaussian model) generated by the machine learning algorithm 112 for each given pixel. Therefore, it can be used to differentiate between defects and noise in the given pixel or in the given group of pixels. If data informative of the noise (e.g., o in a Gaussian model) is low, this indicates that the level of noise present in the given pixel is small. As a consequence, a small difference between the measured pixel intensity and the expected pixel intensity can already indicate the presence of a defect.

The method of FIG. 5A and/or 5B can be performed during run-time scanning of the specimen by an examination tool. Each time a new image is provided by the examination tool (e.g., for each new die), it can be processed according to the method of FIGS. 5A and/or 5B.

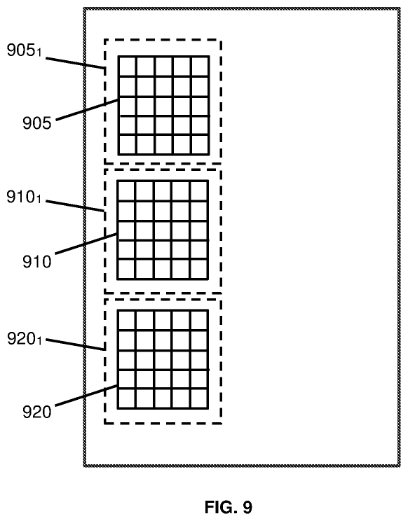

Attention is now drawn to FIGS. 8 and 9, which describe a method of detecting defects in an image, using a plurality of images fed to the machine learning algorithm 112.

The method of FIG. 8 comprises obtaining (operation 800) a first inspection image 9101 informative of a first area 910 of a semiconductor specimen acquired by an examination tool and obtaining (operation 805) at least a second inspection image (905₁, 920₁) informative of a second area (905, 920—different from the first area 910) of the semiconductor specimen. In some examples, a plurality of additional inspection images (each informative of a plurality of different areas of the specimen, all different from the first area) can be obtained. In some examples, each inspection image is informative of an area which corresponds to a die of the specimen.

In some examples, the first area and the second area meet a similarity criterion. For example, they can be informative of similar structural elements (such as similar dies). In some examples, the first area is located at a given location in a first specimen, and the second area is located at the same given location in a second specimen, different from the first specimen (the second specimen being manufactured using the same manufacturing process as the first specimen).

The second inspection image and/or the plurality of additional inspection images can be used as reference images by the machine learning algorithm 112, in order to detect whether the first inspection image include defect(s). The first inspection image and the plurality of additional inspection images can belong to the same image which has been split, or they may have been acquired separately by the examination tool. The first inspection image and the plurality of additional inspection images can be informative of areas of the same specimen, or of different specimens.

According to some examples, the examination tool scans the various areas of the specimen according to a recipe, which dictates the path of the electron beam on the specimen. The recipe indicates the order according to which the various dies/areas of the specimen are acquired.

The first area 910 can correspond to the area for which it has to be (currently) detected whether defects are present, and the second area 920 can correspond to an area acquired by the examination tool after the first area 910 (e.g., immediately after the first area 910). In some examples, the second area can correspond to an area 905 acquired the examination tool before the first area 910. The first area 910 can correspond to the area acquired immediately after the second area 905. For example, the first area 910 corresponds to a given die, the second area 905 corresponds to a die located above the given die, and the second area 920 corresponds to a die located below the given die.

In some examples, the method includes obtaining the first inspection image informative of the first area (such as the first inspection image 910₁), a first additional inspection image informative of an area acquired before the first area (such as the inspection image 905₁) and a second additional inspection image informative of an area acquired after the first area (such as the inspection image 920₁).

The method of FIG. 8 includes feeding (operation 810) at least the first inspection image and the second inspection image to the trained machine learning algorithm 112. If a plurality of additional inspection images has been obtained, the method can include feeding the first inspection image and the plurality of additional inspection images to the trained machine learning algorithm 112.

The machine learning algorithm 112 generates (operation 820), based on the first inspection image and the one or more additional inspection images, for each given pixel of a plurality of pixels of the first inspection image, or for each given group of pixels of a plurality of groups of pixels of the first inspection image (such as the pixels informative of the first area 910) one or more given parameters of a given model. The given model is informative of pixel intensity distribution. In particular, at least part of the given model is informative of pixel intensity distribution in an absence of defects. The given model is also informative of an expected pixel intensity in an absence of defects in the given pixel or in the given group of pixels, and of a probability that a deviation from the expected pixel intensity corresponds to a defect. As mentioned above, the one or more given parameters, or at least part of the given model (as defined by the given parameters) can be used to differentiate between presence of a defect and presence of noise in the given pixel or in the given group of pixels.

The method of FIG. 8 further includes (operation 830), for each given pixel, or for each given group of pixels, using at least some of the one or more given parameters, or at least part of the given model, and measured pixel intensity of the given pixel or of the given group of pixels, to determine whether a defect is present in the given pixel or in the given group of pixels.

A score can be computed for each pixel, based on the given model (see Equations 1, 2 or 3).

If the score is above or equal to a threshold, a defect can be detected in the given pixel (or in the given group of pixels). If the score is below the threshold, this indicates an absence of defects in the given pixel (or in the given group of pixels).

In some examples, for each given pixel, the measured pixel intensity can be compared to the expected pixel intensity of the given pixel. This comparison can be normalized by using the data informative of the confidence (data informative of the noise). The result of the comparison can be compared to a threshold, in order to detect whether a defect is present.

The method of FIG. 8 can be performed during run-time scanning of the specimen by an examination tool. Each time a new image is provided by the examination tool (e.g., for each new die), it can be processed according to the method of FIG. 8.

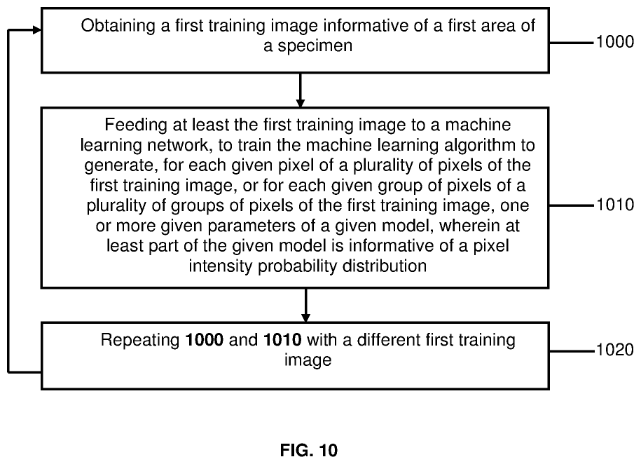

Attention is now drawn to FIG. 10, which describes a method of training the machine learning algorithm 112.

The method of FIG. 10 includes obtaining (operation 1000) a first training image informative of a first area of a specimen. According to some examples, the first training image has been acquired by an examination tool (see reference 101 and/or reference 102). Note that the first inspection image may have been acquired by an optical examination tool, or by an electron beam examination tool, or by another adapted examination tool. The same examination tool can be used, or different examination tools can be used.

In some examples, operation 1000 can include obtaining, in addition to the first training image, one or more (additional) training images, each informative of a different area of the specimen (or, in some examples, of one or more other specimens). In some examples, each area corresponds to a different die of the specimen (or, in some examples, of one or more other specimens). In some examples, the first training image is informative of a first area, and the additional training images are informative of areas meeting a similarity criterion with the first area. For example, the similarity criterion can require that the areas correspond to similar dies of the same specimen (or of another specimen).

In some examples, the first training image is an image in which a defect can be present, and the one or more additional training images correspond to reference images, which are assumed to be free of defects. This is however not limitative.

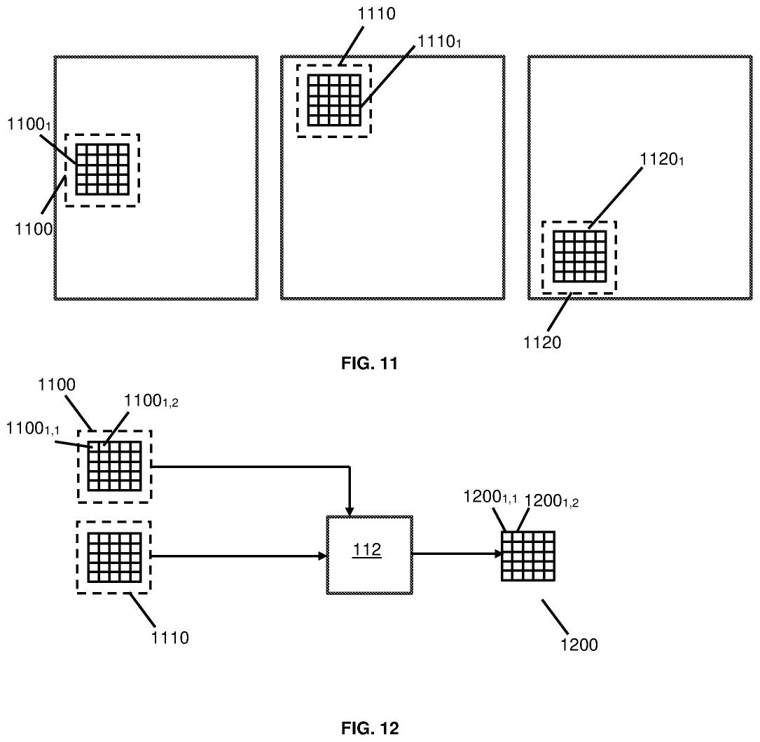

FIG. 11 illustrates a non-limitative example of a plurality of training images which can be fed to machine learning algorithm 112. The first training image 1100 is informative of a first area 1100₁ and the second training image 1110 is informative of a second area 1110₁. According to some examples, the first area 1100₁ and the second area 1110₁ meet a similarity criterion. For example, the similarity criterion can require that the areas both correspond to similar dies of the same specimen (or of another specimen). Similarly, if another training image 1120 informative of a third area 1120₁ is used, according to some examples, the first, second and third areas 1100₁, 1110₁ and 1120₁ can meet a similarity criterion.

The method of FIG. 10 includes feeding (operation 1010) at least the first training image to the machine learning algorithm 112 for its training. If one or more additional training images are used, they can be fed to the machine learning algorithm 112 for its training, in addition to the first training image.

The machine learning algorithm 112 is trained to predict, for each given pixel of a plurality of pixels of the first training image, or for each given group of pixels of a plurality of groups of pixels of the first training image, one or more given parameters of a given model. The given model is informative of a pixel intensity distribution. In particular, at least part of the given model is informative of pixel intensity distribution in an absence of defects in the given pixel or in the given group of pixels (the given model can be used to determine the expected pixel intensity in an absence of defects in the given pixel or in the given group of pixels).

When one or more additional reference images are fed to the machine learning algorithm 112, they can be used by the machine learning algorithm 112 as reference images (in which it is assumed that there is no defect).

In some examples, the machine learning algorithm 112 is trained to predict, for each given pixel of a plurality of pixels of the first training image, or for each given group of pixels of a plurality of groups of pixels of the first training image, data informative of noise present in the given pixel (or in the given group of pixels). As mentioned above, this can correspond to a confidence of the prediction of the expected pixel intensity (in case there is no defect) estimated by the machine learning algorithm 112.

In some examples, the machine learning algorithm 112 is trained to predict one or more values of one or more parameters of a model (such as a probability model) modelling pixel intensity in each pixel or each group of pixels of a plurality of pixels of the first training image. In some examples, the parameters can include data informative of expected pixel intensity in the given pixel or in the given group of pixels (in the absence of defects in the given pixel or in the given group of pixels) and data informative of noise present in each given pixel.

Training of the machine learning algorithm 112 can be performed using methods such as Backpropagation (this is not limitative).

In some examples, the model is a Gaussian model and the machine learning algorithm 112 is trained to determine the average of the model (“u”) and the standard deviation (noted “o”) of the model, for each given pixel of the first training image. The average (“u”) corresponds to the expected pixel intensity of the given pixel, when no defect is present in the pixel. The standard deviation (noted “G”) corresponds to the level of noise present in the given pixel. Note that the Gaussian model is only an example, and other probability models with different parameters and/or with a different number of parameters can be used.

The method of FIG. 10 (operations 1000 and 1010) can be repeated with a different first training image (see operation 1020), which is fed to the machine learning algorithm 112. As mentioned above, operations 1000 and 1010 can include obtaining one or more additional training images and feeding them to the machine learning algorithm 112. The one or more additional training images can be the same at each iteration of the method or can be different. Note that the various training images can be acquired by scanning the specimen at random locations. The various training images may have been acquired by an optical examination tool, or by an electron beam examination tool, or by another adapted examination tool. The method of FIG. 10 can be repeated until a loss function (used to train the machine learning algorithm 112) meets an optimization criterion (e.g., its value is below a threshold).

FIG. 12 illustrates an output of the machine learning algorithm 112 during its training. For each given pixel (1110_{1.1}, 1110_{1,2}, etc.) of the first training image 1110, the machine learning algorithm 112 determines values for the one or more parameters of the corresponding given pixel (noted 1200_{1.1}, 1200_{1.2}, etc.) of the model modelling the pixel intensity in the pixel. A map 1200 of values is therefore obtained.

The loss function used to train the machine learning algorithm 112 can include the measured pixel intensity of each pixel of the first training image, and parameters of the model, which have to be determined. As mentioned above, in some examples, the parameters include data informative of the expected pixel intensity (where no defect is present) to be determined for each pixel and data informative of the noise, to be determined for each pixel. When one or more additional training images are fed to the machine learning model 112 at each iteration for its training, the machine learning algorithm 112 can also use the pixel intensity of these one or more additional training images to determine the parameters during its training.

According to some examples, the loss function includes, for each pixel, a difference between the measured pixel intensity of each pixel of the first training image and the expected pixel intensity (to be determined, where no defect is present), wherein this difference is normalized by the level of noise in the pixel (to be determined).

In some examples in which a Gaussian distribution is used to model the pixel intensity, the following loss function can be used (this equation is not limitative):

$$F = G ( {\sum }_{i} {f}_{i} ( ( μ - curr ) , σ ) )$$

In this equation, i corresponds to the number of pixels in the first training image, “curr” corresponds to the measured pixel intensity of the pixel number i, p corresponds to the expected pixel intensity of pixel number i, should it have been free of defects, o corresponds to an estimate of the noise in pixel number i, f is a function which includes the probability model (Gaussian distribution) modelling the pixel intensity, and G corresponds e.g. to a logarithmic function.

In this example, in which the probability model f is a Gaussian model (this is however not limitative), the machine learning algorithm 112 is trained to determine the average of the model (“μ”) and the standard deviation (noted “σ”) of the model. The average corresponds to the expected pixel intensity of a pixel, when no defect is present in the pixel.

Note that the number of parameters of the model can be greater than two. In addition, the model can be different from a Gaussian model, and any other adapted probability model can be used.

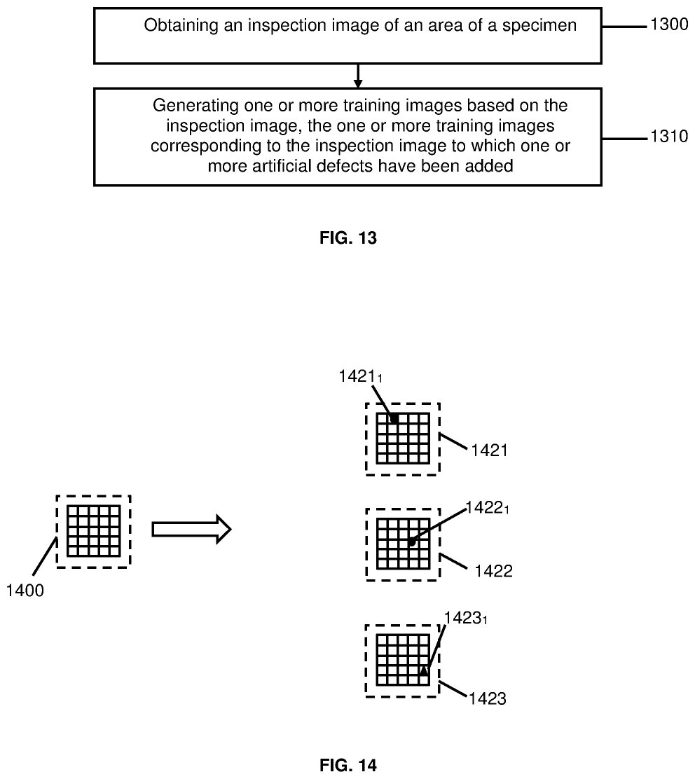

Attention is now drawn to FIGS. 13 and 14.

As mentioned above, the first training image is fed (in some examples, together with one or more additional training images) to the machine learning algorithm 112, for its training.

The first training image is obtained based on acquisition of an area by an examination tool. In some examples, the first training image can correspond to an inspection image acquired by an examination tool, to which one or more artificial defect(s) have been added.

In some examples, an inspection image is acquired (operation 1300) and is used to generate (operation 1310) a plurality of training images. Each given training image of the plurality of training images can be obtained by adding one or more artificial defects to the inspection image. This can be also designated as planting a defect in the inspection image. The position and/or type and/or aspect of the one or more artificial defects can differ between the different training images. This enables augmenting the training set of training images, without requiring performing additional acquisitions.

Each training image generated by the method of FIG. 13 can be used as an input of the training of the machine learning algorithm 112, together with one or more reference training images, as explained with reference to FIG. 10.

FIG. 14 illustrates a non-limitative example of the method of FIG. 13, in which an inspection image 1400 is used to generate three training images 1421, 1422 and 1423. The first training image 1421 corresponds to the inspection image 1400 to which a first artificial defect 1421₁ has been added. The second training image 1422 corresponds to the inspection image 1400 to which a second artificial defect 1422₁ has been added. The third training image 1423 corresponds to the inspection image 1400 to which a third artificial defect 1423₁ has been added. Note that more than one artificial defect can be added to the inspection image.

Note that it is not mandatory to generate training images with artificial defects in order to train the machine learning algorithm 112, and it is possible to use training images corresponding to images acquired from one or more specimens by an examination tool. In some examples, one or more of the training images can correspond to simulated images.

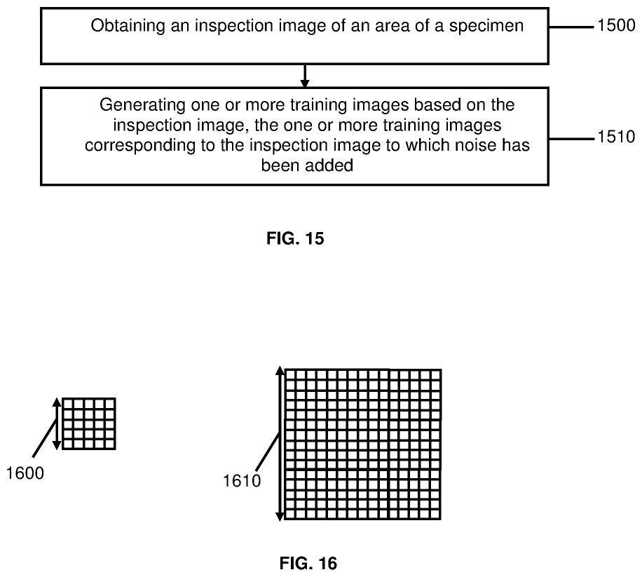

Attention is now drawn to FIG. 15.

When an examination tool acquires the same area of a specimen twice, the image can differ between the two acquisitions. This is due to the presence of noise (generated e.g., by the examination tool). In addition, noise can be caused by the manufacturing process of the specimen. In order to take into account the presence of noise during the training process, the method of FIG. 15 includes obtaining (operation 1500) an inspection image of an area of a specimen (acquired by an examination tool) and adding (operation 1510) noise to the inspection image, in order to generate one or more training images. Note that the inspection image may have been acquired by an optical examination tool, or by an electron beam examination tool, or by another adapted examination tool. A different level of noise can be introduced in the inspection image, in order to generate different training images. The training images can be used in the method of FIG. 10, for training the machine learning algorithm 112.

Attention is now drawn to FIG. 16.

Assume that one or more training images of a first dimension 1600 have been used to train the machine learning algorithm 120. The first dimension 1600 corresponds, e.g., to the height and/or width of the training image(s). Note that the height of the training image(s) is not necessarily the same as their width, and that the first dimension is not necessarily the same for all training images. During the prediction phase, in which the machine learning algorithm 112 is used to determine data informative of the expected pixel intensity (in the absence of defects), inspection images of a second dimension 1610 can be used, in which the second dimension 1610 is different from the first dimension 1600. The second dimension corresponds, e.g., to the height and/or width of the inspection image(s). Note that the height of the inspection image(s) is not necessarily the same as their width, and that the second dimension of the inspection image is not necessarily the same for all inspection images. According to some examples, the first dimension 1600 can be smaller than the second dimension 1610. Note that this ability to use inspection images of greater size than the training images can be ensured by using a convolutional neural network (such as a fully convolutional neural network) as the machine learning algorithm 112. This is however not limitative.

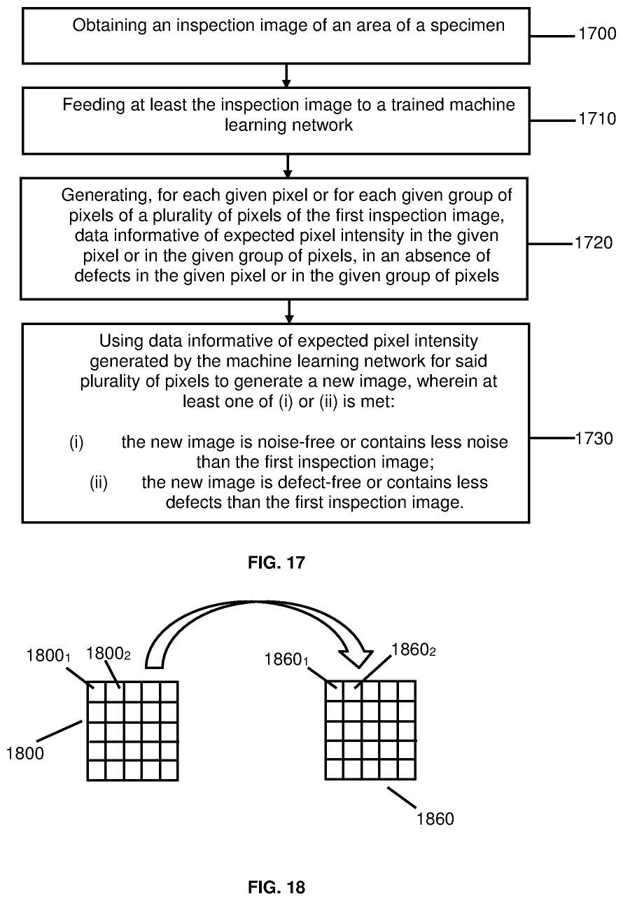

Attention is now drawn to FIG. 17.

The various methods described herein can be used not only to detect defects, but also for other applications, such as (but not limited to), the generation of denoised images and/or defect-free images, as explained hereinafter.

The method of FIG. 17 includes obtaining (operation 1700) an inspection image of an area of a specimen. Note that the inspection image may have been acquired by an optical examination tool, or by an electron beam examination tool, or by another adapted examination tool.

The method of FIG. 17 includes feeding (operation 1710) at least the inspection image to the trained machine learning algorithm 112.

The method of FIG. 17 further includes using (operation 1720) the machine learning algorithm 112 to generate, for each given pixel of a plurality of pixels of the inspection image, or for each given group of pixels of a plurality of groups of pixels of the inspection image, data informative of expected pixel intensity in the given pixel or in the given group of pixels, in an absence of defects in the given pixel or given group of pixels. In particular, the machine learning algorithm 112 can generate, for each given pixel or given group of pixels, one or more given parameters of a given model informative of pixel intensity distribution. The given model (defined by the given parameters), or the given parameters can be used to determine defect-free pixel intensity of the given pixel. In some examples, a median value (or average value) of the given model can be determined, and corresponds to the defect-free pixel intensity of the given pixel. A set of expected pixel intensities (in the absence of defects) is obtained for the pixels of the inspection image.

The method of FIG. 17 further includes using (operation 1730) data informative of expected pixel intensity generated by the machine learning algorithm 112 for the plurality of pixels of the inspection image, to generate a new image. In particular, each pixel (18601, 18602, etc.) of the new image 1860 can be assigned with the expected pixel intensity (in the absence of defects) calculated for the corresponding pixel (with the same position-see e.g., 1800₁, 1800₂, etc.) in the inspection image.

The new image is a denoised image. In particular, the noise present in the new image is smaller than the noise present in the inspection image. In some examples, the noise is cancelled in the new image. The new image is defect-free or contains less defects than the inspection image. The new image can be used for various applications, such as a reference image. In some examples, the new image can be used as a reference image provided to the machine learning algorithm 112, together with an inspection image, in order to detect defect(s) in the inspection image, both in the prediction phase (see e.g., FIG. 8) and/or in the training phase (see e.g., FIG. 10).

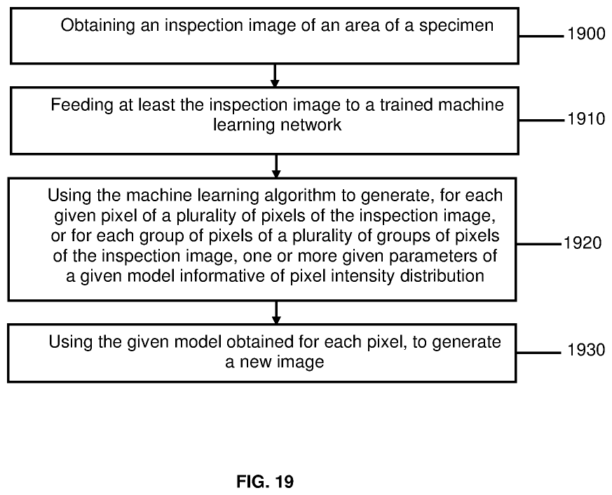

Attention is now drawn to FIG. 19.

The various methods described herein can be used not only to detect defects, but also for other applications, such as (but not limited to), the generation of new images. For example, it can occur that the number of available inspection images is not enough. The method of FIG. 19 enables generating artificially new images, which look similar to actual inspection images. This enables augmenting the size of the training set, with realistic images.

The method of FIG. 19 includes obtaining (operation 1900) an inspection image 2000 of an area of a specimen. Note that the inspection image 2000 may have been acquired by an optical examination tool, or by an electron beam examination tool, or by another adapted examination tool.

The method of FIG. 19 includes feeding (operation 1910) at least the inspection image 2000 to the trained machine learning algorithm 112.

The method of FIG. 19 further includes using (operation 1920) the machine learning algorithm 112 to generate, for each given pixel of a plurality of pixels of the inspection image 2000, or for each group of pixels of a plurality of groups of pixels of the inspection image 2000, one or more given parameters of a given model informative of pixel intensity distribution (also called pixel intensity probability distribution, statistical model, probability model or probability function). The pixel intensity probability distribution is usable to determine a probability that the measured pixel intensity of the given pixel or the given group of pixels corresponds to a defect.

The method of FIG. 19 further includes using (operation 1930) the given model obtained for each pixel, to generate a new image (or a plurality of new images).

In particular, each given pixel (2060₁, 2060₂, etc.) of the new image 2060 can be assigned with a pixel intensity value, randomly generated based on the given model obtained for the corresponding given pixel (2000₁, 2000₂, etc.) of the inspection image 2000. Indeed, since the given model corresponds to a pixel intensity probability distribution, it is possible to randomly generate value(s) for pixel intensity which match the probability distribution.

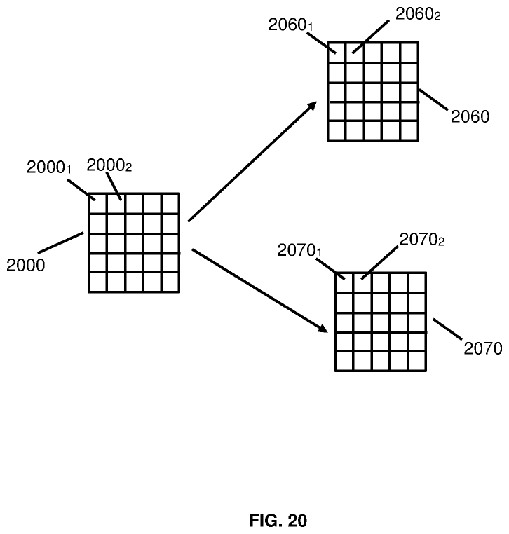

In FIG. 20, an additional new image 2070 is generated. Each given pixel (2070₁, 2070₂, etc.) of the new image 2070 can be assigned with a pixel intensity value, randomly generated based on the given model obtained for the corresponding given pixel (2000₁, 2000₂, etc.) of the inspection image 2000.

One or more new images are obtained, which look similar to the inspection image, but remain different from the inspection image. The one or more new images can be used for example for training of the machine learning algorithm 112, or for other applications.

Note that another particular application of the method of FIG. 19 can be the generation of a new image with less defects and/or less noise, as explained with reference to FIG. 17.

In the detailed description, numerous specific details have been set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, as apparent from the aforementioned discussions, it is appreciated that throughout the specification discussions utilizing terms such as “obtaining”, “applying”, “determining”, “performing”, “using”, “estimating”, “training”, “feeding”, or the like, refer to the action(s) and/or process(es) of a computer that manipulate and/or transform data into other data, said data represented as physical, such as electronic, quantities and/or said data representing the physical objects.

The terms “computer” or “computer-based system” should be expansively construed to include any kind of hardware-based electronic device with a data processing circuitry (e.g., digital signal processor (DSP), a GPU, a TPU, a field programmable gate array (FPGA), an application specific integrated circuit (ASIC), microcontroller, microprocessor etc.), including, by way of non-limiting example, the computer-based system 103 of FIG. 1 and respective parts thereof disclosed in the present application. The data processing circuitry (designated also as processing circuitry) can comprise, for example, one or more processors operatively connected to computer memory, loaded with executable instructions for executing operations, as further described below. The data processing circuitry encompasses a single processor or multiple processors, which may be located in the same geographical zone, or may, at least partially, be located in different zones, and may be able to communicate together. The one or more processors can represent one or more general-purpose processing devices such as a microprocessor, a central processing unit, or the like. More particularly, a given processor may be one of: a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

It is to be noted that while the present disclosure refers to the processing circuitry 104 being configured to perform various functionalities and/or operations, the functionalities/operations can be performed by the one or more processors of the processing circuitry 104 in various ways. By way of example, the operations described hereinafter can be performed by a specific processor, or by a combination of processors. The operations described hereinafter can thus be performed by respective processors (or processor combinations) in the processing circuitry 104, while, optionally, at least some of these operations may be performed by the same processor. The present disclosure should not be limited to be construed as one single processor always performing all the operations.

The term “specimen” used in this specification should be expansively construed to cover any kind of wafer, masks, and other structures, combinations and/or parts thereof used for manufacturing semiconductor integrated circuits, magnetic heads, flat panel displays, and other semiconductor-fabricated articles.

The term “examination” used in this specification should be expansively construed to cover any kind of metrology-related operations as well as operations related to detection and/or classification of defects in a specimen during its fabrication. Examination is provided by using non-destructive examination tools during or after manufacture of the specimen to be examined. By way of non-limiting example, the examination process can include runtime scanning (in a single or in multiple scans), sampling, reviewing, measuring, classifying and/or other operations provided with regard to the specimen or parts thereof using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes, atomic force microscopes, optical inspection tools, etc.

By way of non-limiting example, run-time examination can employ a two-phase procedure, e.g., inspection of a specimen followed by review of sampled locations of potential defects. During the first phase, the surface of a specimen is inspected at high-speed and relatively low-resolution. In the first phase, a defect map is produced to show suspected locations on the specimen having high probability of a defect. During the second phase, at least some of the suspected locations are more thoroughly analyzed with relatively high resolution. In some cases, both phases can be implemented by the same inspection tool, and, in some other cases, these two phases are implemented by different inspection tools.

The term “noise” can include variations in an image acquired by an examination tool, with respect to the intended design. The noise can be caused for example by the examination tool and/or by the manufacturing process (process variations, etc.).

The term “defect” includes abnormality or undesirable feature formed on or within a specimen. In some examples, the defect can include noise with an amplitude of variation (with respect to the intended design) above a certain threshold (the threshold can be selected by the manufacturer). The threshold can be different depending on the type of feature, the type of manufacturing process, etc., or other considerations.

The term “design data” used in the specification should be expansively construed to cover any data indicative of hierarchical physical design (layout) of a specimen. Design data can be provided by a respective designer and/or can be derived from the physical design (e.g., through complex simulation, simple geometric and Boolean operations, etc.). Design data can be provided in different formats such as, by way of non-limiting examples, GDSII format, OASIS format, etc. Design data can be presented in vector format, grayscale intensity image format, or otherwise.

It is appreciated that, unless specifically stated otherwise, certain features of the presently disclosed subject matter, which are described in the context of separate embodiments, can also be provided in combination in a single embodiment.

Conversely, various features of the presently disclosed subject matter, which are described in the context of a single embodiment, can also be provided separately, or in any suitable sub-combination. In the following detailed description, numerous specific details are set forth in order to provide a thorough understanding of the methods and apparatus.

In embodiments of the presently disclosed subject matter, fewer, more, and/or different stages than those shown in the methods of FIGS. 2, 5, 8, 10, 13, 15, 17 and 19 may be executed. In embodiments of the presently disclosed subject matter, one or more stages illustrated in the methods of FIGS. 2, 5, 8, 10, 13, 15, 17 and 19 may be executed in a different order, and/or one or more groups of stages may be executed simultaneously.

It is to be understood that the invention is not limited in its application to the details set forth in the description contained herein or illustrated in the drawings.

It will also be understood that the system according to the invention may be, at least partly, implemented on a suitably programmed computer. Likewise, the invention contemplates a computer program being readable by a computer for executing the method of the invention. The invention further contemplates a non-transitory computer-readable memory tangibly embodying a program of instructions executable by the computer for executing the method of the invention.

The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

What is claimed is:

1. A system comprising one or more processing circuitries configured to:
obtain a first inspection image informative of a first area of a semiconductor specimen acquired by an examination tool,
feed at least the first inspection image to a machine learning algorithm configured to determine, for each given pixel of a plurality of pixels of the first inspection image, or for each given group of pixels of a plurality of groups of pixels of the first inspection image, one or more given parameters of a given model informative of pixel intensity distribution,
for said each given pixel, or said each given group of pixels, use:
at least one of the one or more given parameters, or at least part of the given model associated with the one or more given parameters, and
measured pixel intensity of the given pixel or of the given group of pixels,
to determine whether a defect is present in the given pixel or in the given group of pixels.

2. The system of claim 1, configured to, for said each given pixel or for said each given group of pixels, use at least some of the one or more given parameters, or at least part of the given model associated with the one or more given parameters, to determine a probability that a defect is present in the given pixel or in the given group of pixels.

3. The system of claim 1, wherein, for said each given pixel or for said each given group of pixels, at least part of the given model associated with the one or more given parameters is informative of a pixel intensity probability distribution usable to determine a probability that the measured pixel intensity of the given pixel or of the given group of pixels corresponds to a defect.

4. The system of claim 1, wherein, for said each given pixel or for said each given group of pixels, at least one of the one or more given parameters, or at least part of the given model associated with the one or more given parameters, is usable to determine an expected pixel intensity in an absence of defects in the given pixel or in the given group of pixels.

5. The system of claim 1, wherein, for said each given pixel or for said each given group of pixels, at least one of the one or more given parameters, or at least part of the given model associated with the one or more given parameters, is usable to determine:
an expected pixel intensity in an absence of defects in the given pixel or in the given group of pixels, and
a probability that a deviation from the expected pixel intensity corresponds to a defect.

6. The system of claim 1, configured to use the given model to detect, on average, in different regions with a different level of noise, a maximal number of defects below a same threshold for said different regions.

7. The system of claim 1, configured to, for said each given pixel or for said each given group of pixels, use at least some of the one or more given parameters, or at least part of the given model associated with the one or more given parameters, to differentiate between presence of a defect and presence of noise in the given pixel or in the given group of pixels.

8. The system of claim 1, wherein the one or more given parameters are determined by the machine learning algorithm specifically for said each given pixel or said each given group of pixels, wherein the one or more given parameters, or data derived thereof, comprise:
data informative of an expected pixel intensity in the given pixel, or in the given group of pixels, in an absence of defects in the given pixel, or in the given group of pixels;
at least one of:
data informative of noise present in the given pixel, or in the given group of pixels;
data informative of a confidence associated with the data informative of expected pixel intensity in the given pixel or in the given group of pixels;
data enabling normalization of noise present in the given pixel or in the given group of pixels; or
data enabling differentiating between defects and noise in the given pixel or in the given group of pixels.

9. The system of claim 1, configured to feed, to the machine learning algorithm, in addition to the first inspection image, one or more reference images informative of one or more other areas of the semiconductor specimen, or of another semiconductor specimen.

10. The system of claim 1, wherein the machine learning algorithm has been trained with at least one training image and a loss function comprising, for each given pixel of a plurality of pixels of the training image, or for each group of pixels of a plurality of group of pixels of the training image, one or more parameters of a model modelling pixel intensity associated with the given pixel or with the given group of pixels.

11. The system of claim 1, wherein at least one of (i) or (ii) is met:
(i) the machine learning algorithm is configured to determine, for each given pixel of a plurality of pixels of the first inspection image, or for each given group of pixels of a plurality of groups of pixels of the first inspection image, at the same time:
data informative of expected pixel intensity in the given pixel or in the given group of pixels, in an absence of defects in the given pixel or in the given group of pixels, and
data informative of noise present in the given pixel or in the given group of pixels;
(ii) the same machine learning algorithm is configured to determine, for each given pixel of a plurality of pixels of the first inspection image, or for each given group of pixels of a plurality of groups of pixels of the first inspection image:
data informative of expected pixel intensity in the given pixel or in the given group of pixels, in an absence of defects in the given pixel or in the given group of pixels, and
data informative of noise present in the given pixel or in the given group of pixels.

12. The system of claim 1, configured to:
obtain a single inspection image informative of an area of a semiconductor specimen acquired by the examination tool,
determine one or more defects in the area based on the single inspection image, said determination comprising:
feeding the single inspection image to the machine learning algorithm configured to determine, for each given pixel of a plurality of pixels of the single inspection image, or for each given group of pixels of a plurality of groups of pixels of the first inspection image, one or more given parameters of a given model informative of pixel intensity distribution, and
for said each given pixel, or said each given group of pixels, using at least one of the one or more given parameters, or at least part of the given model associated with the one or more given parameters, and measured pixel intensity of the given pixel or of the given group of pixels, to determine whether a defect is present in the given pixel or in the given group of pixels.

13. The system of claim 1, wherein one or more training images used to train the machine learning algorithm have at least one of a smaller height or a smaller width than the first inspection image.

14. The system of claim 1, configured to use at least one of the one or more given parameters, or at least part of the given model associated with the one or more given parameters, to generate a new image, wherein at least one of (i) or (ii) is met:
(i) the new image is noise-free or contains less noise that the first inspection image;
(ii) the new image is defect-free or contains less defects than the first inspection image.

15. A system comprising one or more processing circuitries configured to:
obtain:
a first training image informative of a first area of a semiconductor specimen acquired by an examination tool,
feed at least the first training image to the machine learning algorithm, to train the machine learning algorithm to determine, for each given pixel of a plurality of pixels of the first training image, or for each given group of pixels of a plurality of groups of pixels of the first training image, one or more given parameters of a given model informative of pixel intensity distribution, wherein the one or more given parameters, or the given model associated with the one or more given parameters, is usable to detect presence of a defect in the given pixel or in the given group of pixels.

16. The system of claim 15, wherein, for said each given pixel or for said each given group of pixels, the one or more given parameters, or the given model associated with the one or more given parameters, is usable to determine pixel intensity in an absence of defects in the given pixel or in the given group of pixels.

17. The system of claim 15, wherein one or more training images used to train the machine learning algorithm correspond to one or more inspection images of a semiconductor specimen, to which one or more artificial defects have been added.

18. A non-transitory computer readable medium comprising instructions that, when executed by at least one or more processing circuitries, cause the at least one or more processing circuitries to perform:
obtaining a first inspection image informative of a first area of a semiconductor specimen acquired by an examination tool,
feeding at least the first inspection image to a machine learning algorithm configured to determine, for each given pixel of a plurality of pixels of the first inspection image, or for each given group of pixels of a plurality of groups of pixels of the first inspection image, one or more given parameters of a given model informative of pixel intensity distribution,
for said each given pixel, or said each given group of pixels, using:
at least one of the one or more given parameters, or at least part of the given model associated with the one or more given parameters, and
measured pixel intensity of the given pixel or of the given group of pixels,
to determine whether a defect is present in the given pixel or in the given group of pixels.

19. A non-transitory computer readable medium comprising instructions that, when executed by one or more processing circuitries, cause the one or more processing circuitries to perform:
obtaining a first inspection image informative of a first area of a semiconductor specimen acquired by an examination tool,
feeding at least the first inspection image to a machine learning algorithm configured to determine, for each given pixel of a plurality of pixels of the first inspection image, or for each given group of pixels of a plurality of groups of pixels of the first inspection image, one or more given parameters of a given model informative of pixel intensity distribution,
for said each given pixel, or said each given group of pixels, using at least one of the one or more given parameters, or at least part of the given model associated with the one or more given parameters, to determine a new given pixel intensity value,
thereby obtaining a set of new given pixel intensity values, and
using the set of new given pixel intensity values to generate a new image.

20. The non-transitory computer readable medium of claim 19, wherein:
each new given pixel intensity value corresponds to a given expected pixel intensity in an absence of defects in the given pixel or in the given group of pixels, and
the set of new given pixel intensity values corresponds to a set of given expected pixel intensity values,
wherein at least one of (i) or (ii) is met:
(i) the new image is noise-free or contains less noise that the first inspection image;
(ii) the new image is defect-free or contains less defects than the first inspection image.
